(19) United States
(12) Patent Application Publication
(10) Pub. No.: US 2026/0282957 A1
(43) Pub. Date: Sep. 17, 2026

(54) PACKAGE CARRIER STRUCTURE AND MANUFACTURING METHOD THEREOF

(71) Applicant: Unimicron Technology Corp., Taoyuan City (TW)

(72) Inventors: Tzyy-Jang Tseng, Taoyuan City (TW); Guang-Hwa Ma, Hsinchu City (TW); Chin-Sheng Wang, Taoyuan City (TW); Ra-Min Tain, Hsinchu County (TW)

(73) Assignee: Unimicron Technology Corp., Taoyuan City (TW)

(21) Appl. No.: 19/257,449

(22) Filed: Jul. 1, 2025

Related U.S. Application Data
(60) Provisional application No. 63/769,752, filed on Mar. 11, 2025.

(30) Foreign Application Priority Data
May 22, 2025 (TW) 114205176

(51) Int. Cl. H10W 70/63; H10W 70/05; H10W 70/692

(52) U.S. Cl. CPC H10W 70/635; H10W 70/095; H10W 70/692

(57) ABSTRACT

A package carrier structure and a manufacturing method thereof are provided. The package carrier structure includes a glass substrate, at least one through substrate via and an interconnect structure. The glass substrate has a first surface and a second surface opposite to the first surface. The at least one through substrate via penetrates through the glass substrate. The interconnect structure is disposed on the first surface of the glass substrate. The interconnect structure includes a first dielectric layer, a plurality of conductive layers and a plurality of conductive vias. The plurality of conductive layers is disposed in the first dielectric layer. The plurality of conductive vias is disposed in the first dielectric layer and connected between adjacent conductive layers.

### CROSS-REFERENCE TO RELATED APPLICATION

This application claims the priority benefit of U.S. provisional application serial no. 63/769,752, filed on Mar. 11, 2025 and Taiwan application serial no. 114205176, filed on May 22, 2025. The entirety of each of the above-mentioned patent applications is hereby incorporated by reference herein and made a part of this specification.

### BACKGROUND

### Technical Field

The disclosure relates to a structure and a manufacturing method thereof, and more particularly to a package carrier structure and a manufacturing method thereof.

### Description of Related Art

Three-dimensional packaging technology uses a silicon interposer to connect a chip and a component in a vertical direction to increase packaging density and improve overall performance. As the industry’s demand for high-performance computing increases, the packaging size gradually increases to accommodate more electronic components to achieve high-performance computing. However, the increase in packaging size causes the interposer to easily warp, resulting in reduced reliability and affecting performance. Therefore, how to make the package carrier structure applicable to high-performance computing and have good reliability is a current goal to be improved.

### SUMMARY

The disclosure provides a package carrier structure and a manufacturing method thereof, which have improved reliability and reduced cost.

A package carrier structure of the disclosure includes a glass substrate, at least one through substrate via, and an interconnect structure. The glass substrate has a first surface and a second surface opposite to the first surface. The at least one through substrate via penetrates through the glass substrate. The interconnect structure is disposed on the first surface of the glass substrate. The interconnect structure includes a first dielectric layer, a plurality of conductive layers, and a plurality of conductive vias. The plurality of conductive layers are disposed in the first dielectric layer. The plurality of conductive vias are disposed in the first dielectric layer and connected between adjacent ones of the plurality of conductive layers.

In an embodiment of the disclosure, a layer of the plurality of conductive layers closest to the glass substrate includes at least one pad portion. The at least one pad portion corresponds to and directly contacts the at least one through substrate via.

In an embodiment of the disclosure, a width of the at least one pad portion is less than a width of the at least one through substrate via.

In an embodiment of the disclosure, a width of a side of the plurality of conductive vias close to the glass substrate is greater than a width of a side of the plurality of conductive vias away from the glass substrate.

In an embodiment of the disclosure, the package carrier structure further includes a second dielectric layer disposed between the glass substrate and the interconnect structure. The at least one through substrate via further penetrates through the second dielectric layer.

In an embodiment of the disclosure, the second dielectric layer directly contacts and is bonded to the first dielectric layer.

In an embodiment of the disclosure, the first dielectric layer directly contacts and is bonded to the first surface of the glass substrate.

In an embodiment of the disclosure, the package carrier structure further includes a chip disposed on the interconnect structure and electrically connected to the interconnect structure.

In an embodiment of the disclosure, a contact of the chip directly contacts and is bonded to a corresponding one of the plurality of conductive vias in the interconnect structure.

In an embodiment of the disclosure, the package carrier structure further includes a circuit substrate disposed on the second surface of the glass substrate and electrically connected to the at least one through substrate via.

A manufacturing method of a package carrier structure of the disclosure includes the following steps. An interconnect structure is formed on a temporary carrier. The interconnect structure includes a first dielectric layer, a plurality of conductive layers, and a plurality of conductive vias. The plurality of conductive layers are disposed in the first dielectric layer. The plurality of conductive vias are disposed in the first dielectric layer and connected between adjacent ones of the plurality of conductive layers. A glass substrate is provided, and a through substrate via is formed in the glass substrate. The interconnect structure is bonded to the glass substrate. The temporary carrier is removed.

In an embodiment of the disclosure, a topmost layer of the plurality of conductive layers of the interconnect structure on the temporary carrier includes a pad portion, and a top surface of the pad portion is coplanar with the first dielectric layer.

In an embodiment of the disclosure, bonding the interconnect structure to the glass substrate includes the following steps. The interconnect structure is faced toward a first surface of the glass substrate. The pad portion of the interconnect structure is disposed corresponding to the through substrate via in the glass substrate. A hybrid bonding process is performed such that a metal-to-metal bonding is performed on the pad portion of the interconnect structure and the through substrate via.

In an embodiment of the disclosure, during a performance of the hybrid bonding process, a dielectric-to-dielectric bonding is performed on the first dielectric layer of the interconnect structure and the first surface of the glass substrate.

In an embodiment of the disclosure, forming the through substrate via in the glass substrate includes the following steps. A second dielectric layer is formed on the first surface of the glass substrate. A through hole passing through the first surface and a second surface of the glass substrate and the second dielectric layer is formed. The second surface is opposite to the first surface. A conductive material is filled in the through hole to form the through substrate via.

In an embodiment of the disclosure, during a performance of the hybrid bonding process, a dielectric-to-dielectric bonding is performed on the first dielectric layer of the interconnect structure and the second dielectric layer.

In an embodiment of the disclosure, a width of the pad portion is less than a width of the through substrate via.

In an embodiment of the disclosure, a width of a side of the plurality of conductive vias close to the glass substrate is greater than a width of a side of the plurality of conductive vias away from the glass substrate.

In an embodiment of the disclosure, the manufacturing method further includes mounting a chip on the interconnect structure. A contact of the chip is bonded to a corresponding one of the plurality of conductive vias in the interconnect structure.

In an embodiment of the disclosure, the manufacturing method further includes the following step. The glass substrate is mounted on a circuit substrate.

Based on the above, the package carrier structure uses a glass substrate as an intermediate layer and attaches the interconnect structure to the glass substrate through hybrid bonding, so that one side of the glass substrate can be bonded to a chip having fine circuits and the other side is connected to a circuit substrate. This way, the possibility of warpage occurring in the package carrier structure can be reduced, production cost can be lowered, and reliability can be improved. The structure is applicable to large-size packaging and can be applied in high-performance computing.

### BRIEF DESCRIPTION OF THE DRAWINGS

FIG. 1 is a cross-sectional schematic diagram of a package carrier structure according to an embodiment of the disclosure.

FIG. 2 is a cross-sectional schematic diagram of another package carrier structure according to another embodiment of the disclosure.

FIGS. 3A to 3G are cross-sectional schematic diagrams of a manufacturing process of a package carrier structure according to an embodiment of the disclosure.

### DESCRIPTION OF THE EMBODIMENTS

In the drawings, for clarity, the thicknesses of layers, films, panels, regions, and so on are enlarged. Throughout the specification, the same reference numerals indicate the same elements. It is understood that when an element such as a layer, film, region, or substrate is referred to as being “on” or “connected to” another element, it may be directly on or connected to the other element, or intervening elements may also be present. In contrast, when an element is referred to as being “directly on” or “directly connected to” another element, there are no intervening elements. As used herein, “connected” can refer to physical and/or electrical connection. Furthermore, “electrically connected” or “coupled” may involve the presence of other elements between two elements.

It is understood that although the terms “first,” “second,” and the like may be used herein to describe various elements, components, regions, layers, and/or portions, these elements, components, regions, layers, and/or portions should not be limited by these terms. These terms are only used to distinguish one element, component, region, layer, or portion from another element, component, region, layer, or portion. Therefore, a “first” element, component, region, layer, or portion discussed below could be termed a second element, component, region, layer, or portion without departing from the teachings of this disclosure.

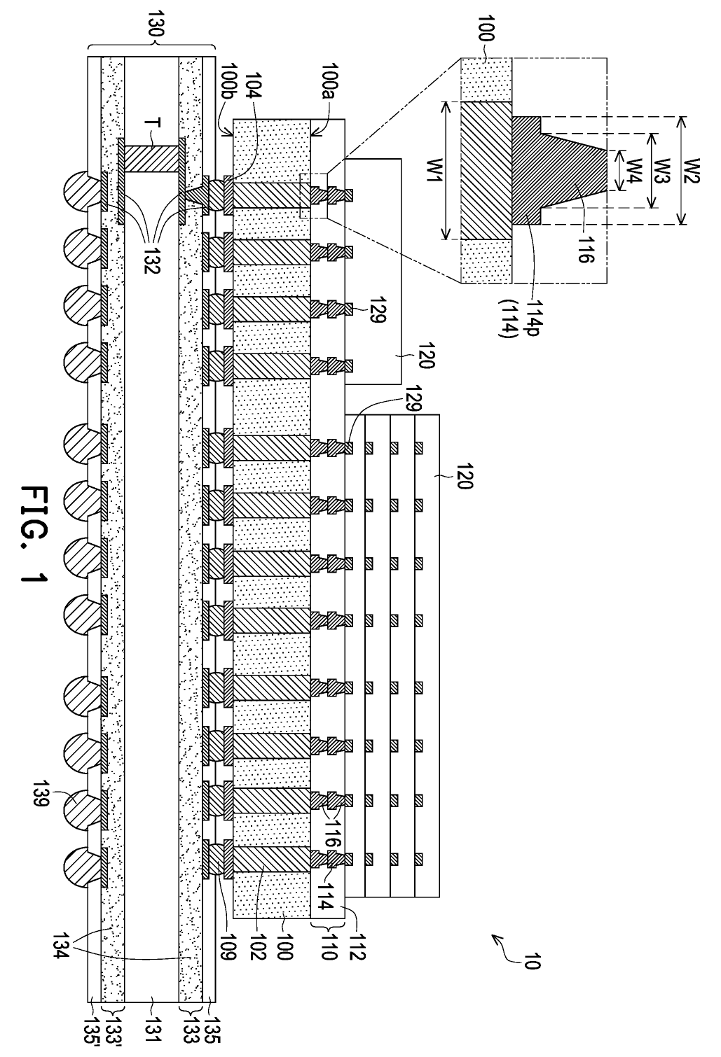

FIG. 1 is a cross-sectional schematic diagram of a package carrier structure according to an embodiment of the disclosure.

Referring to FIG. 1, a package carrier structure 10 includes a glass substrate 100, a through substrate via 102, and an interconnect structure 110. The glass substrate 100 has a first surface 100a and a second surface 100b opposite to the first surface 100a. The through substrate via 102 penetrates through the glass substrate 100. The interconnect structure 110 is disposed on the first surface 100a of the glass substrate 100. The interconnect structure 110 includes a first dielectric layer 112 and a plurality of conductive layers 114 and a plurality of conductive vias 116 disposed in the first dielectric layer 112. The conductive vias 116 may be connected between adjacent ones of the conductive layers 114.

In some embodiments, the glass substrate 100 may include a quartz glass substrate, a phosphosilicate glass substrate, a borophosphosilicate glass substrate, a fluosilicate glass substrate, or another suitable glass substrate, but the disclosure is not limited thereto.

In some embodiments, the first dielectric layer 112 directly contacts and is bonded to the glass substrate 100. In some embodiments, a covalent bond is formed at an interface between the first dielectric layer 112 and the glass substrate 100. In some embodiments, a material of the first dielectric layer 112 includes silicon oxide or another suitable dielectric material, but the disclosure is not limited thereto.

In some embodiments, a layer of the plurality of conductive layers 114 closest to the glass substrate 100 may include at least one pad portion 114p. The pad portion 114p directly contacts and is bonded to a corresponding through substrate via 102.

In some embodiments, a width W2 of the pad portion 114p may be smaller than a width W1 of the through substrate via 102.

In some embodiments, the conductive via 116 is tapered. In some embodiments, a width W3 of the conductive via 116 on a side close to the glass substrate 100 is greater than a width W4 of the conductive via 116 on a side away from the glass substrate 100.

In some embodiments, a width W2 of the pad portion 114p is greater than a width W3 of the conductive via 116 on a side close to the glass substrate 100.

In some embodiments, a conductive pad 104 may be disposed on the second surface 100b of the glass substrate 100. The conductive pad 104 is disposed corresponding to and covering the through substrate via 102 to facilitate external connection of the through substrate via 102. In some embodiments, an additional dielectric layer, conductive layer, and conductive via (not shown) may also be formed on the second surface 100b of the glass substrate 100, so as to form an additional interconnect structure on the second surface 100b of the glass substrate 100, similar to the interconnect structure 110 described above.

In some embodiments, materials of the through substrate via 102, the conductive layer 114, and the conductive via 116 may include copper, titanium, tungsten, aluminum, tantalum, gold, silver, a combination thereof, or another suitable conductive material, but the disclosure is not limited thereto.

In some embodiments, the package carrier structure 10 further includes a chip 120 and a circuit substrate 130. The chip 120 is disposed on the interconnect structure 110 and electrically connected to the interconnect structure 110. The circuit substrate 130 is disposed on the second surface 100b of the glass substrate 100 and electrically connected to the through substrate via 102.

In some embodiments, a contact 129 of the chip 120 directly contacts and is bonded to a corresponding conductive via 116 in the interconnect structure 110. The chip 120 may be electrically connected to the through substrate via 102 through the interconnect structure 110.

In some embodiments, a bottom surface of the chip 120 may directly contact a top surface of the interconnect structure 110.

In some embodiments, the chip 120 may include a logic chip, a memory chip, a system-on-chip, or another suitable chip, but the disclosure is not limited thereto. In some embodiments, the chip 120 may be a three-dimensional chip composed of a plurality of stacked dies.

In some embodiments, the circuit substrate 130 includes a core layer 131, build-up structures 133 and 133’, and protective layers 135 and 135’. The build-up structures 133 and 133’ are respectively disposed on opposite sides of the core layer 131, and the protective layers 135 and 135’ are respectively disposed on the build-up structures 133 and 133’. In some embodiments, the circuit substrate 130 further includes a conductive through hole T, which penetrates the core layer 131 to electrically connect the build-up structures 133 and 133’ located on both sides of the core layer 131. In some embodiments, the build-up structures 133 and 133’ each include alternately stacked circuit layers 132 and dielectric layers 134.

In some embodiments, the materials of the core layer 131 and the dielectric layer 134 may each include epoxy resin impregnated glass fiber cloth, Ajinomoto build-up film material, bismaleimide triazine (BT) resin, or another suitable material, but the disclosure is not limited thereto.

In some embodiments, the materials of the circuit layer 132 and the conductive through hole T may include copper, titanium, tungsten, aluminum, tantalum, gold, silver, a combination thereof, or another suitable conductive material, but the disclosure is not limited thereto. In some embodiments, the protective layers 135 and 135’ may be, for example, solder resist layers, but the disclosure is not limited thereto.

In some embodiments, the glass substrate 100 may be bonded to the circuit substrate 130 through a conductive connector 109. The conductive connector 109 may be connected between the conductive pad 104 and the topmost circuit layer 132 of the build-up structure 133, so that the chip 120 may be electrically connected to the circuit substrate 130 through the interconnect structure 110, the through substrate via 102, and the conductive connector 109. In some embodiments, a material of the conductive connector 109 may include solder balls, metal bumps, conductive adhesive, or another suitable material, but the disclosure is not limited thereto.

In some embodiments, the circuit substrate 130 further includes a conductive terminal 139, which is disposed on a side of the circuit substrate 130 away from the glass substrate 100 and electrically connected to the circuit layer 132 of the build-up structure 133’, so as to provide external connection of the package carrier structure 10. In some embodiments, a material of the conductive terminal 139 may include solder balls, metal bumps, conductive adhesive, or another suitable material, but the disclosure is not limited thereto.

In some embodiments, the circuit substrate 130 may be an integrated circuit substrate, a printed circuit board, or another suitable circuit substrate, but the disclosure is not limited thereto.

The package carrier structure 10 of this embodiment uses the glass substrate 100 as an intermediate layer, and the first surface 100a of the glass substrate 100 is bonded to the first dielectric layer 112 of the interconnect structure 110, and the through substrate via 102 is bonded to the pad portion 114p of the interconnect structure 110. Therefore, through the interconnect structure 110 disposed on the glass substrate 100 and the through substrate via 102 in the glass substrate 100, the chip 120 can be connected to the circuit substrate 130, thereby reducing the possibility of warpage, lowering production cost, improving reliability, and being applicable to large-size packaging and usable in high-performance computing.

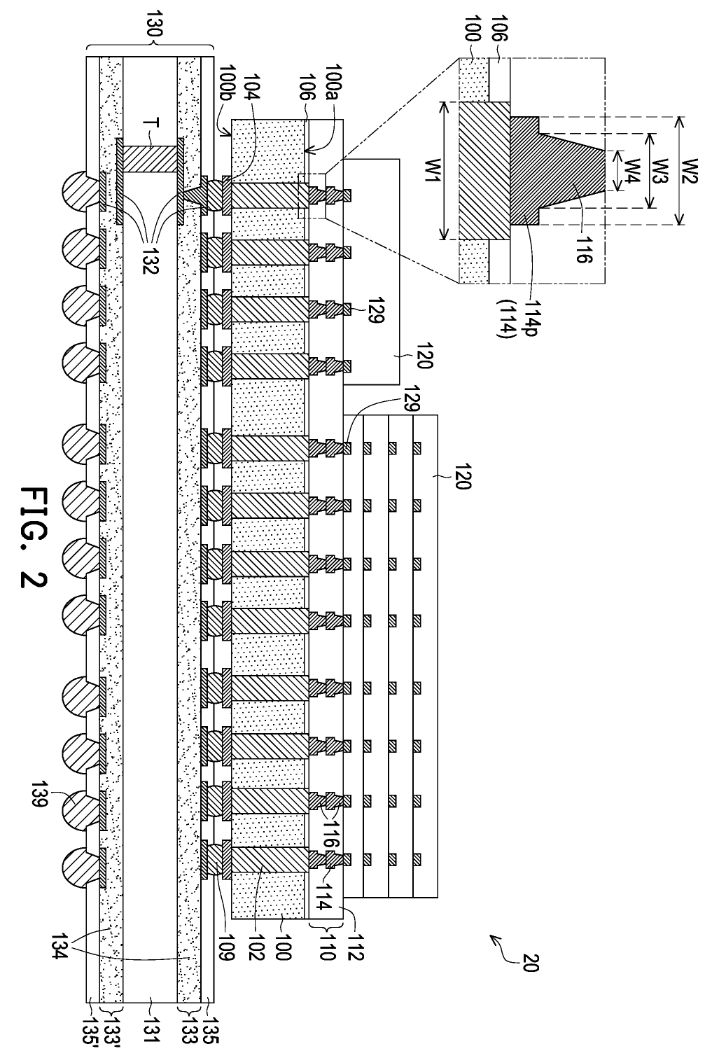

FIG. 2 is a cross-sectional schematic diagram of a package carrier structure according to another embodiment of the disclosure. It should be noted that the embodiment of FIG. 2 continues the reference numerals and part of the content of the embodiment of FIG. 1, in which the same or similar reference numerals are used to indicate the same or similar elements, and the description of the same technical content is omitted. The description of the omitted parts can be referred to the foregoing embodiment and will not be repeated here.

Referring to FIG. 2, a main difference between a package carrier structure 20 of FIG. 2 and the package carrier structure 10 of FIG. 1 is that the package carrier structure 20 further includes a second dielectric layer 106. The second dielectric layer 106 is disposed on the first surface 100a of the glass substrate 100 and located between the glass substrate 100 and the interconnect structure 110, so as to facilitate bonding between the glass substrate 100 and the interconnect structure 110.

In some embodiments, the through substrate via 102 further penetrates the second dielectric layer 106. That is, a top surface of the through substrate via 102 may be higher than the first surface 100a of the glass substrate 100. In some embodiments, the top surface of the through substrate via 102 may be substantially coplanar with a top surface of the second dielectric layer 106.

In some embodiments, the second dielectric layer 106 directly contacts and is bonded to the first dielectric layer 112. In some embodiments, a covalent bond is formed at an interface between the second dielectric layer 106 and the first dielectric layer 112. In some embodiments, a material of the second dielectric layer 106 is the same as a material of the first dielectric layer 112. A material of the second dielectric layer 106 may include silicon oxide or another suitable dielectric material, but the disclosure is not limited thereto.

The package carrier structure 20 of this embodiment uses the glass substrate 100 as an intermediate layer, and the first surface 100a of the glass substrate 100 is bonded to the first dielectric layer 112 of the interconnect structure 110 through the second dielectric layer 106, and the through substrate via 102 is bonded to the pad portion 114p of the interconnect structure 110. Therefore, through the interconnect structure 110 disposed on the glass substrate 100 and the through substrate via 102 in the glass substrate 100, the chip 120 can be connected to the circuit substrate 130, thereby reducing the possibility of warpage, lowering production cost, improving reliability, and being applicable to large-size packaging and usable in high-performance computing.

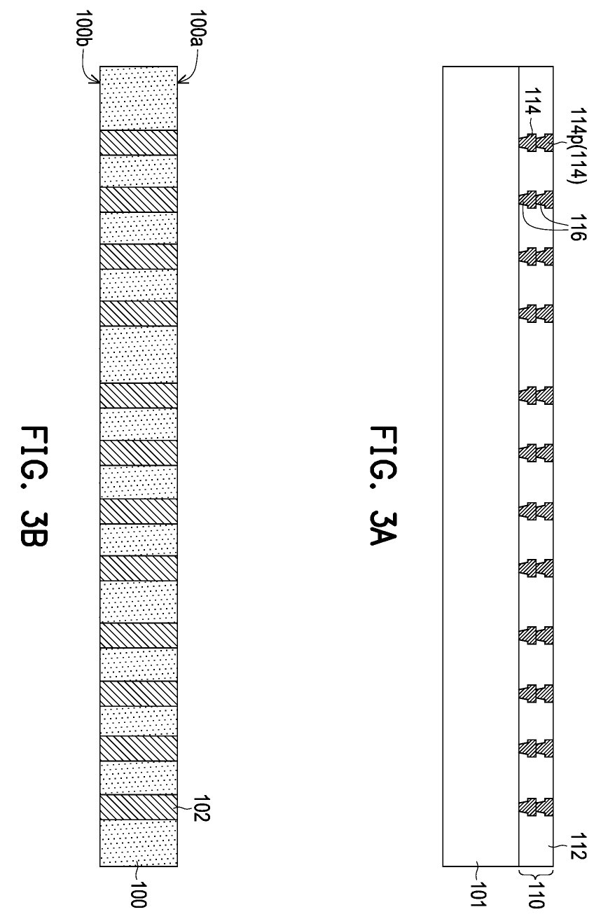

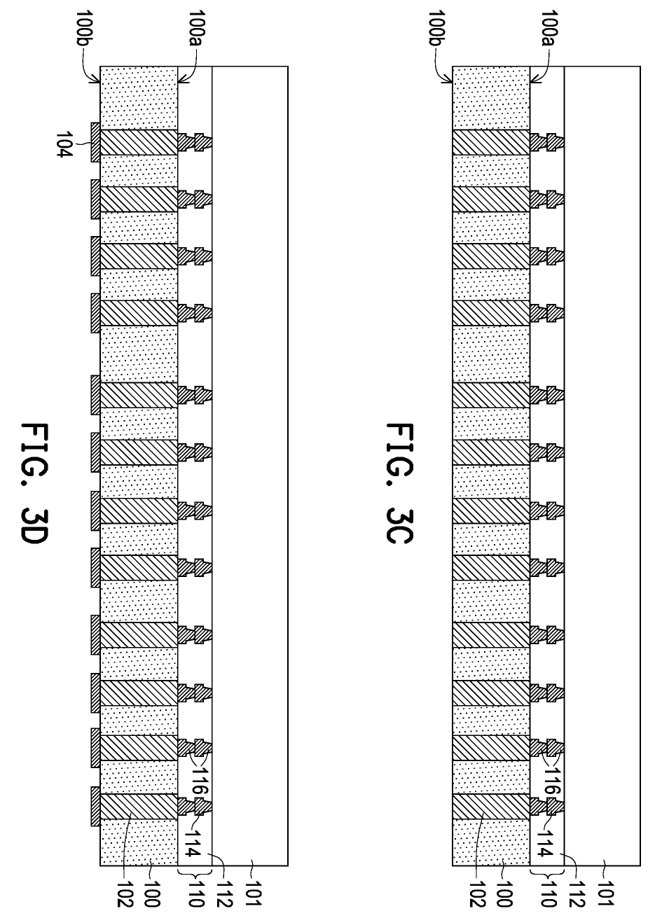

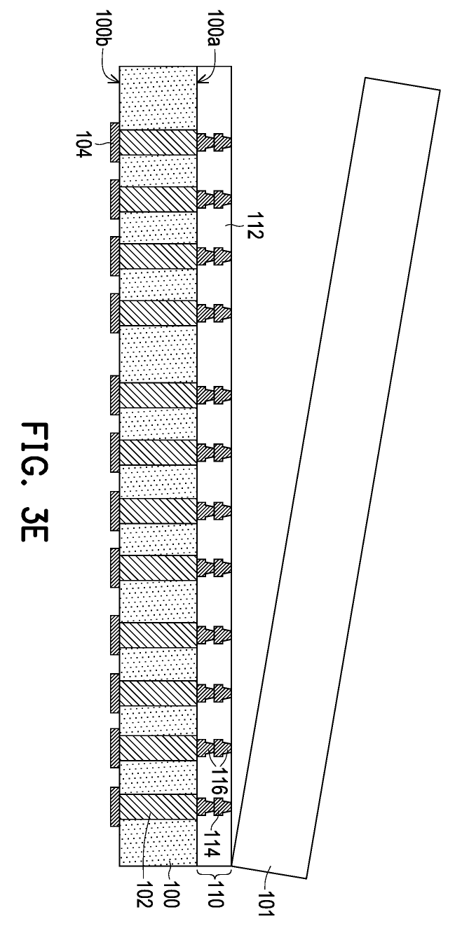

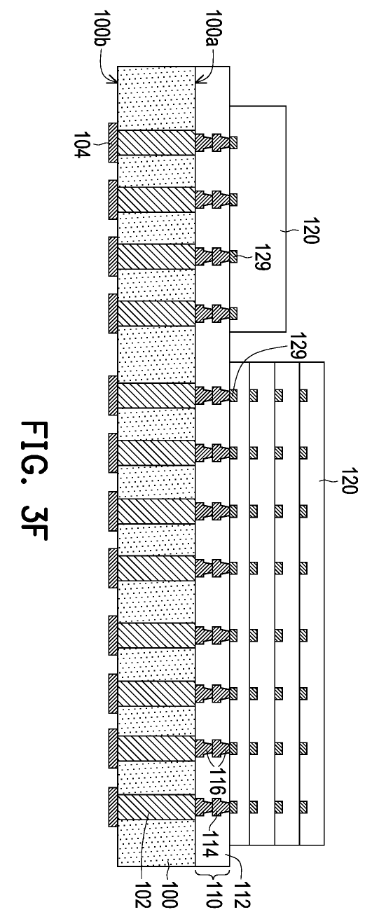

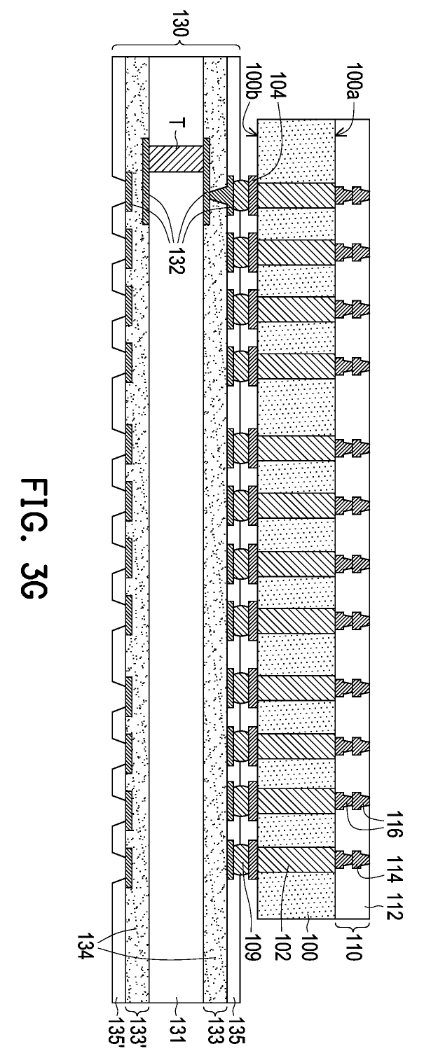

FIGS. 3A to 3G are cross-sectional schematic diagrams of a manufacturing process of a package carrier structure according to an embodiment of the disclosure. It should be noted that the embodiment of FIGS. 3A to 3G continues the reference numerals and part of the content of the embodiment of FIG. 1, in which the same or similar reference numerals are used to indicate the same or similar elements, and the description of the same technical content is omitted. The description of the omitted parts can be referred to the foregoing embodiment and will not be repeated here.

Referring to FIG. 3A, a temporary carrier 101 is provided, and an interconnect structure 110 is formed on the temporary carrier 101. The conductive layer 114 and the conductive via 116 in the interconnect structure 110 may be formed through a dual damascene process, but the disclosure is not limited thereto. For example, a dielectric material layer (not shown) may first be formed on the temporary carrier 101, and then the dielectric material layer may be patterned through photolithography and etching processes to form an opening corresponding to the pattern of the conductive via and an opening corresponding to the pattern of the conductive layer (not shown). A conductive material layer (not shown) is formed in the openings and a planarization process (e.g., a chemical mechanical polishing process, a mechanical polishing process, or the like) is performed to form a first conductive layer 114 and a conductive via 116 in the openings and make a top surface of the conductive layer 114 coplanar with the dielectric material layer. The above steps are repeated until a predetermined number of conductive layers are formed, thereby completing fabrication of the interconnect structure 110. Accordingly, the dielectric layer 112 is formed by stacking a plurality of dielectric material layers.

Referring to FIG. 3B, a glass substrate 100 is provided, and a through substrate via 102 is formed in the glass substrate 100. For example, a through hole passing through a first surface 100a and a second surface 100b of the glass substrate 100 may be formed in the glass substrate 100 by a drilling process, and then a conductive material is filled into the through hole to form the through substrate via 102.

In some embodiments, before forming the through hole through the glass substrate 100, a second dielectric layer (not shown; reference may be made to FIG. 2) may be first formed on the first surface 100a of the glass substrate 100, and then the drilling process is performed, so that the through hole penetrates the glass substrate 100 and the second dielectric layer.

In some embodiments, after the conductive material is formed, a planarization process (e.g., a chemical mechanical polishing process, a mechanical polishing process, or the like) may be performed to remove excess conductive material on the first surface 100a and the second surface 100b of the glass substrate 100, and make one end of the through substrate via 102 coplanar with the first surface 100a of the glass substrate 100 (or a top surface of the second dielectric layer, if any), and the other end of the through substrate via 102 coplanar with the second surface 100b of the glass substrate 100.

Referring to FIG. 3C, through hybrid bonding, the interconnect structure 110 is bonded to the glass substrate 100. For example, the interconnect structure 110 may be faced toward the first surface 100a of the glass substrate 100, and the pad portion 114p of the interconnect structure 110 is disposed corresponding to the through substrate via 102 in the glass substrate 100, so that metal-to-metal bonding (e.g., copper-to-copper bonding) is performed between the pad portion 114p and the through substrate via 102, and the dielectric layer 112 of the interconnect structure 110 may undergo dielectric-to-dielectric bonding with the first surface 100a of the glass substrate 100 (or a top surface of the second dielectric layer, if any), to form a covalent bond at an interface between the dielectric layer 112 and the glass substrate 100 (or the second dielectric layer, if any). This way, the glass substrate 100 and the interconnect structure 110 can be well bonded, so that a fine circuit can be formed on the glass substrate 100, facilitating subsequent connection with a chip. In addition, since the interconnect structure 110 is independently formed and then attached to the glass substrate 100 after formation, the possibility of the glass substrate 100 being damaged or cracked during the process can be reduced.

Referring to FIG. 3D, a conductive pad 104 is formed on the second surface 100b of the glass substrate 100. The conductive pad 104 covers one end of the through substrate via 102.

Referring to FIG. 3E, the temporary carrier 101 is removed.

Referring to FIG. 3F, the chip 120 is mounted on the interconnect structure 110. For example, a contact 129 of the chip 120 may be bonded to a corresponding conductive via 116 in the interconnect structure 110 through metal-to-metal bonding (e.g., copper-to-copper bonding).

Then, referring to FIG. 1, the glass substrate 100 is mounted on the circuit substrate 130. For example, the glass substrate 100 may be bonded to a corresponding circuit layer 132 in the circuit substrate 130 through a conductive connector 109.

In some embodiments, a conductive terminal 139 may be formed on a side of the circuit substrate 130 away from the glass substrate 100.

The above-described embodiment installs the chip 120 on the glass substrate 100 first and then bonds the glass substrate 100 carrying the chip 120 to the circuit substrate 130. However, the disclosure does not limit the mounting order of the chip 120 and the circuit substrate 130. In other embodiments, as shown in FIGS. 3G and 1, the glass substrate 100 may be mounted on the circuit substrate 130 first, and then the chip 120 is mounted on the glass substrate 100.

Based on the above, manufacturing of the package carrier structure 10 can be generally completed.

In summary, the package carrier structure of the disclosure uses a glass substrate as an intermediate layer and attaches the interconnect structure to the glass substrate through hybrid bonding, so that one side of the glass substrate can be bonded to a chip having fine circuits and the other side is connected to a circuit substrate. This way, the possibility of warpage occurring in the package carrier structure can be reduced, production cost can be lowered, and reliability can be improved. The structure is applicable to large-size packaging and can be applied in high-performance computing.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A package carrier structure, comprising:
a glass substrate, having a first surface and a second surface opposite to the first surface;
at least one through substrate via, penetrating through the glass substrate; and
an interconnect structure, disposed on the first surface of the glass substrate, wherein the interconnect structure comprises:
a first dielectric layer;
a plurality of conductive layers, disposed in the first dielectric layer; and
a plurality of conductive vias, disposed in the first dielectric layer and connected between adjacent ones of the plurality of conductive layers.

2. The package carrier structure according to claim 1, wherein a layer of the plurality of conductive layers closest to the glass substrate comprises at least one pad portion, and the at least one pad portion corresponds to and directly contacts the at least one through substrate via.

3. The package carrier structure according to claim 2, wherein a width of the at least one pad portion is less than a width of the at least one through substrate via.

4. The package carrier structure according to claim 1, wherein a width of a side of the plurality of conductive vias close to the glass substrate is greater than a width of a side of the plurality of conductive vias away from the glass substrate.

5. The package carrier structure according to claim 1, further comprising:
a second dielectric layer, disposed between the glass substrate and the interconnect structure, wherein the at least one through substrate via further penetrates through the second dielectric layer.

6. The package carrier structure according to claim 5, wherein the second dielectric layer directly contacts and is bonded to the first dielectric layer.

7. The package carrier structure according to claim 1, wherein the first dielectric layer directly contacts and is bonded to the first surface of the glass substrate.

8. The package carrier structure according to claim 1, further comprising:
a chip, disposed on the interconnect structure and electrically connected to the interconnect structure.

9. The package carrier structure according to claim 8, wherein a contact of the chip directly contacts and is bonded to a corresponding one of the plurality of conductive vias in the interconnect structure.

10. The package carrier structure according to claim 1, further comprising:
a circuit substrate, disposed on the second surface of the glass substrate and electrically connected to the at least one through substrate via.

11. A manufacturing method of a package carrier structure, comprising:
forming an interconnect structure on a temporary carrier, wherein the interconnect structure comprises:
a first dielectric layer;
a plurality of conductive layers, disposed in the first dielectric layer; and
a plurality of conductive vias, disposed in the first dielectric layer and connected between adjacent ones of the plurality of conductive layers;
providing a glass substrate and forming a through substrate via in the glass substrate;
bonding the interconnect structure to the glass substrate; and
removing the temporary carrier.

12. The manufacturing method of the package carrier structure according to claim 11, wherein a topmost layer of the plurality of conductive layers of the interconnect structure on the temporary carrier comprises a pad portion, and a top surface of the pad portion is coplanar with the first dielectric layer.

13. The manufacturing method of the package carrier structure according to claim 12, wherein bonding the interconnect structure to the glass substrate comprises:
facing the interconnect structure toward a first surface of the glass substrate;
correspondingly disposing the pad portion of the interconnect structure and the through substrate via in the glass substrate; and
performing a hybrid bonding process such that a metal-to-metal bonding is performed on the pad portion of the interconnect structure and the through substrate via.

14. The manufacturing method of the package carrier structure according to claim 12, wherein during a performance of a hybrid bonding process, a dielectric-to-dielectric bonding is performed on the first dielectric layer of the interconnect structure and a first surface of the glass substrate.

15. The manufacturing method of the package carrier structure according to claim 13, wherein forming the through substrate via in the glass substrate comprises:
forming a second dielectric layer on the first surface of the glass substrate;
forming a through hole passing through the first surface and a second surface of the glass substrate and the second dielectric layer, wherein the second surface is opposite to the first surface; and
filling a conductive material in the through hole to form the through substrate via.

16. The manufacturing method of the package carrier structure according to claim 15, wherein during a performance of the hybrid bonding process, a dielectric-to-dielectric bonding is performed on the first dielectric layer of the interconnect structure and the second dielectric layer.

17. The manufacturing method of the package carrier structure according to claim 12, wherein a width of the pad portion is less than a width of the through substrate via.

18. The manufacturing method of the package carrier structure according to claim 11, wherein a width of a side of the plurality of conductive vias close to the glass substrate is greater than a width of a side of the plurality of conductive vias away from the glass substrate.

19. The manufacturing method of the package carrier structure according to claim 11, further comprising:
mounting a chip on the interconnect structure, wherein a contact of the chip is bonded to a corresponding one of the plurality of conductive vias in the interconnect structure.

20. The manufacturing method of the package carrier structure according to claim 11, further comprising:
mounting the glass substrate on a circuit substrate.
